(19) United States
(12) Patent Application Publication
(10) Pub. No.: US 2026/0123118 A1
(43) Pub. Date: Apr. 30, 2026

(54) DISPLAY DEVICE

(71) Applicant: AUO Corporation, Hsinchu City (TW)

(72) Inventors: Jen-Hung Huang, Hsinchu City (TW); Yu-Pin Kuo, Hsinchu City (TW); Ming-Lung Chen, Hsinchu City (TW); Jia Hao Hsu, Hsinchu City (TW); Kun-Cheng Tien, Hsinchu City (TW)

(73) Assignee: AUO Corporation, Hsinchu City (TW)

(21) Appl. No.: 19/344,350

(22) Filed: Sep. 29, 2025

(30) Foreign Application Priority Data
Oct. 30, 2024 (TW) 113141442

(51) Int. Cl. H10H 20/855; H10H 20/01; H10K 59/38; H10K 59/80

(52) U.S. Cl. CPC H10H 20/855; H10H 20/0363; H10K 59/38; H10K 59/879; H10K 59/8792

(57) ABSTRACT

A display device includes a first substrate, a first light-emitting unit, a barrier layer, a first light-shielding layer, a second light-shielding layer, and a first dielectric layer. First light-emitting unit includes light-emitting layer. First light-emitting unit is disposed on first substrate. First substrate includes groove area. First light-emitting unit is disposed in groove area. Barrier layer surrounds first light-emitting unit. Barrier layer has top surface. Distance between top surface and first surface of first substrate along third direction is greater than distance between light-emitting layer of first light-emitting unit and first surface of first substrate. First light-shielding layer includes first opening, is disposed on first substrate, and surrounds first light-emitting unit. Second light-shielding layer is disposed on first light-shielding layer and has second opening. First dielectric layer has first refractive index and is disposed between first light-shielding layer and second light-shielding layer and on first lighting unit.

### CROSS-REFERENCE TO RELATED APPLICATION

This application claims the priority benefit of Taiwan application serial no. 113141442, filed on Oct. 30, 2024. The entirety of the above-mentioned patent application is hereby incorporated by reference herein and made a part of this specification.

### BACKGROUND

### Technical Field

The disclosure relates to a display device.

### Related Art

Currently, for existing display devices, in order to improve the utilization rate of light from light-emitting components, adopting white materials that reflect and recycle light with optical mechanical structures is a common concept. However, with the current micro light-emitting diode mass transfer technology, the misalignment of micro light-emitting diodes cannot be avoided, causing the optical structure to be unable to accurately correspond to the absolute position of the micro light-emitting diodes. This results in the photoresist layer covering the micro light-emitting diodes, causing reduced light emission efficiency or excessive retreat, greatly reducing the optical gain effect, and simultaneously causing metal electrodes to be exposed, thereby increasing the reflectance of the light-emitting components. Additionally, when micro light-emitting diodes are miniaturized into vertical micro LEDs, under the same equipment capability, the coverage area ratio becomes larger, further covering the micro light-emitting diode surface or retreat design. This will seriously affect the subsequent metal wiring yield. Currently, how to make the optical mechanical structure ideally and completely approach and surround the micro light-emitting diodes without covering the light-emitting surface, so as to maintain low viewing angle color shift and low reflection while being able to more efficiently enhance the packaging architecture to avoid optoelectronic problems is very important.

### SUMMARY

The disclosure provides a display device, including a first substrate, a first light-emitting unit, a barrier layer, a first light-shielding layer, a second light-shielding layer, and a first dielectric layer. The first light-emitting unit includes a light-emitting layer, the first light-emitting unit is disposed on the first substrate, the first substrate includes a groove area, the first light-emitting unit is disposed in the groove area, the barrier layer surrounds the first light-emitting unit, the barrier layer has a top surface, and a distance between the top surface and a first surface of the first substrate along a third direction is greater than a distance between the light-emitting layer and the first surface of the first substrate. The first light-shielding layer includes a first opening, is disposed on the first substrate, and surrounds the first light-emitting unit. The second light-shielding layer is disposed on the first light-shielding layer, and has a second opening. The first dielectric layer has a first refractive index, is disposed between the first light-shielding layer and the second light-shielding layer, and is positioned on the first light-emitting unit. The first light-emitting unit has a first length along a first direction and has a second length along a second direction, the first opening has a third length along the first direction, the first opening has a fourth length along the second direction, the second opening has a fifth length along the first direction, the second opening has a sixth length along the second direction, the fifth length is greater than the third length, the sixth length is greater than the fourth length, the fifth length is greater than the first length, the sixth length is greater than the second length, a difference between the third length and the first length is less than or equal to 3 micrometers and greater than or equal to zero, and a difference between the fourth length and the second length is less than or equal to 3 micrometers and greater than or equal to zero.

Based on the above, in the display device of embodiments of the disclosure, the first light-emitting unit is disposed in the groove area, the barrier layer surrounds the first light-emitting unit, the distance between the top surface of the barrier layer and the first surface of the first substrate along the third direction is greater than the distance between the light-emitting layer and the first surface of the first substrate, the first light-shielding layer includes a first opening, the second light-shielding layer is disposed on the first light-shielding layer and has a second opening, the first dielectric layer has a first refractive index and is disposed between the first light-shielding layer and the second light-shielding layer and located on the first light-emitting unit, the first light-emitting unit has a first length along the first direction and has a second length along the second direction, the first opening has a third length along the first direction, the first opening has a fourth length along the second direction, the second opening has a fifth length along the first direction, the second opening has a sixth length along the second direction, the fifth length is greater than the third length, the sixth length is greater than the fourth length, the fifth length is greater than the first length, the sixth length is greater than the second length, and the difference between the third length and the first length is less than or equal to 3 micrometers and greater than or equal to zero and the difference between the fourth length and the second length is less than or equal to 3 micrometers and greater than or equal to zero. In this way, through the foregoing design, the display device may have low viewing angle color shift and low reflection performance while being able to more efficiently enhance the packaging architecture.

### BRIEF DESCRIPTION OF THE DRAWINGS

FIG. 1A to FIG. 1J show schematic diagrams of partial process flows of a display device manufacturing method according to an embodiment of the disclosure.

FIG. 1K to FIG. 1R show schematic diagrams of partial process flows of a display device manufacturing method according to another embodiment of the disclosure.

FIG. 2 is a top view schematic diagram of a display device according to an embodiment of the disclosure.

FIG. 3A is a cross-sectional schematic diagram of the display device according to FIG. 1 along I-I′.

FIG. 3B is a cross-sectional schematic diagram of the display device along II-II′ according to FIG. 1.

FIG. 4A is a cross-sectional schematic diagram of a display device according to another embodiment of the disclosure.

FIG. 4B is a cross-sectional schematic diagram of a display device according to another embodiment of the disclosure.

FIG. 4C is a cross-sectional schematic diagram of a display device according to another embodiment of the disclosure.

FIG. 4D is a cross-sectional schematic diagram of a display device according to another embodiment of the disclosure.

FIG. 5A is a top view schematic diagram of a display device according to another embodiment of the disclosure.

FIG. 5B is a cross-sectional schematic diagram according to the display device in FIG. 5A.

FIG. 5C is a cross-sectional schematic diagram according to the display device in FIG. 5A.

FIG. 5D to FIG. 5G are enlarged schematic diagrams of the lens layer according to FIG. 5B or FIG. 5C.

FIG. 6A is a cross-sectional schematic diagram of a display device according to another embodiment of the disclosure.

FIG. 6B is a cross-sectional schematic diagram of a display device according to another embodiment of the disclosure.

FIG. 6C is a cross-sectional schematic diagram of a display device according to another embodiment of the disclosure.

FIG. 6D is a cross-sectional schematic diagram of a display device according to another embodiment of the disclosure.

FIG. 7A to FIG. 7F show schematic diagrams of partial process flows of a display device manufacturing method according to another embodiment of the disclosure.

FIG. 8A to FIG. 8F show schematic diagrams of partial process flows of a display device manufacturing method according to another embodiment of the disclosure.

### DESCRIPTION OF THE EMBODIMENTS

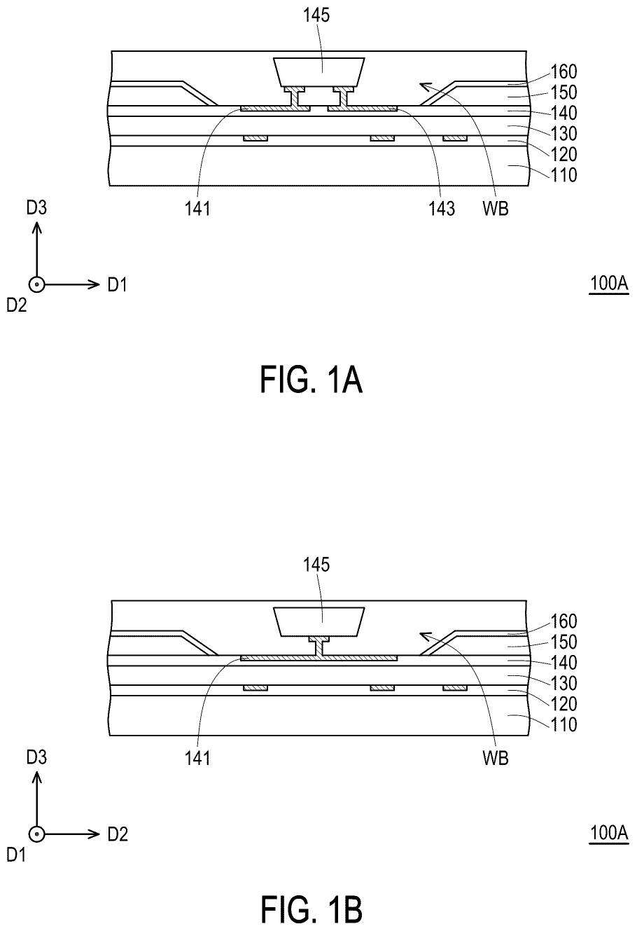

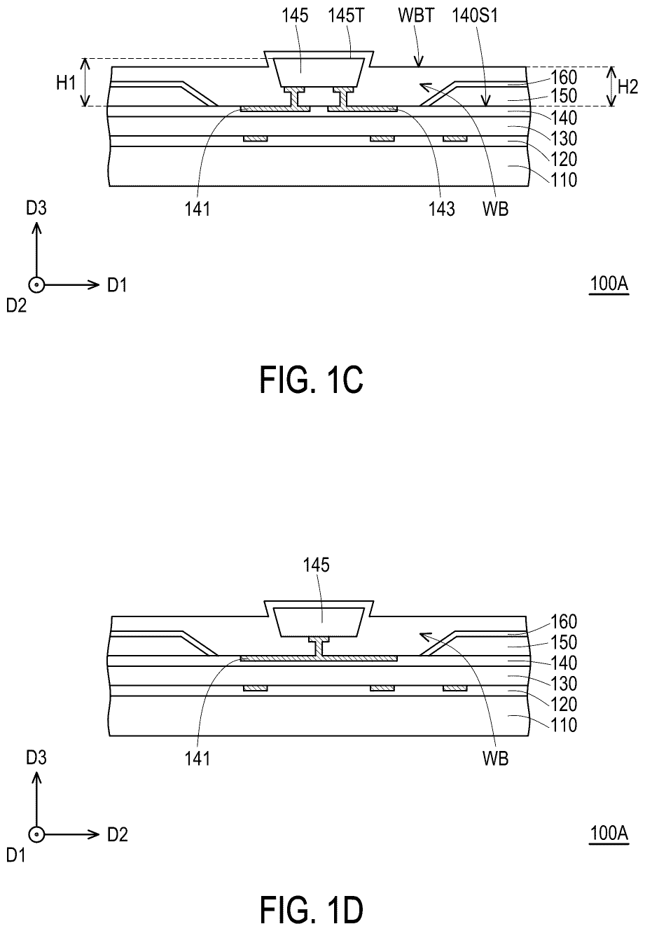

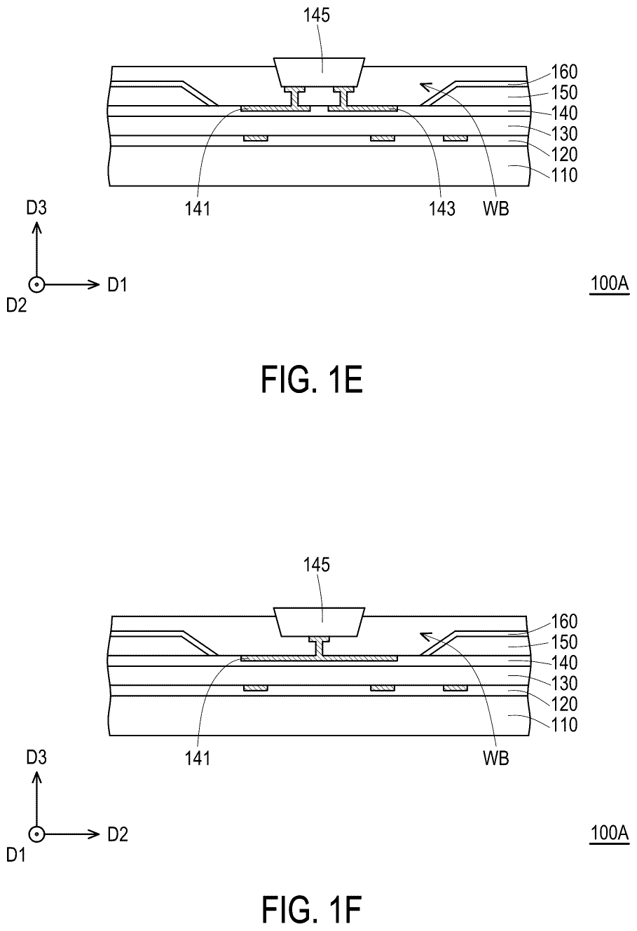

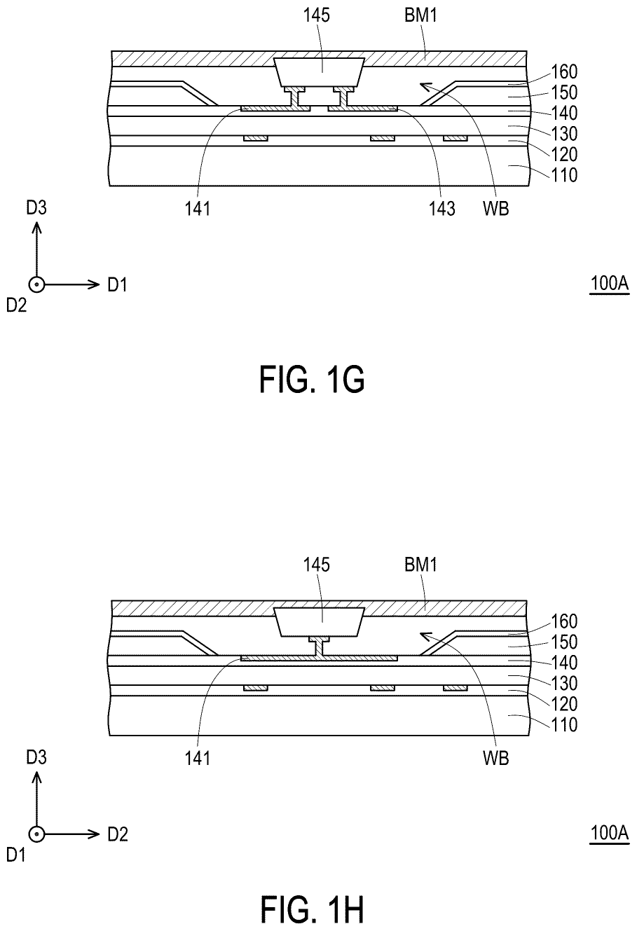

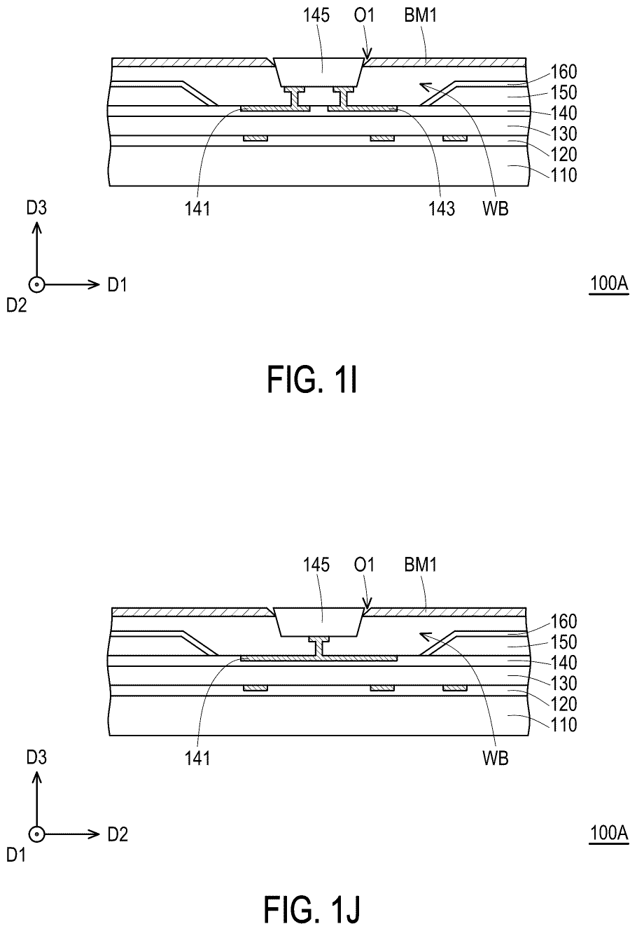

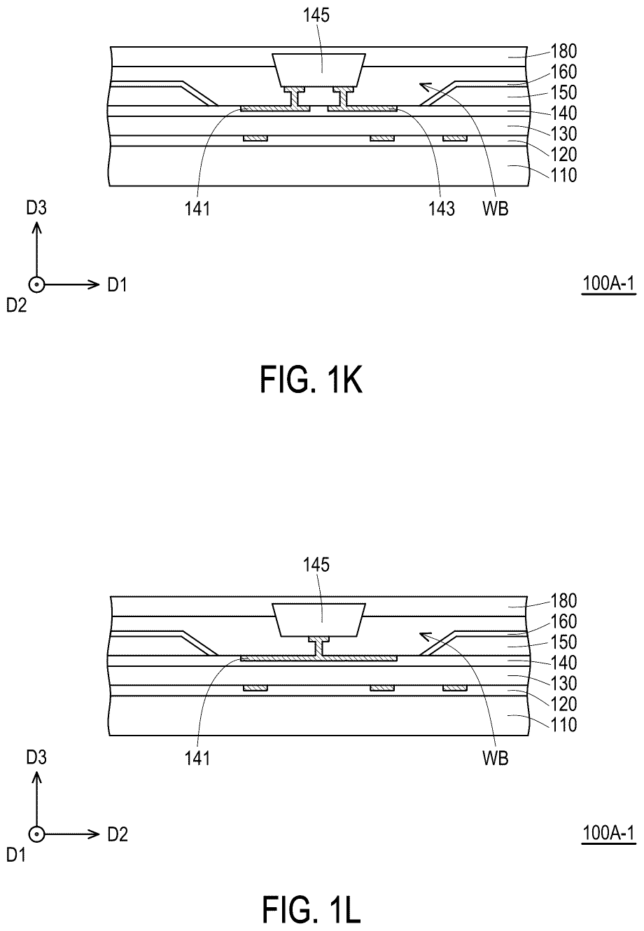

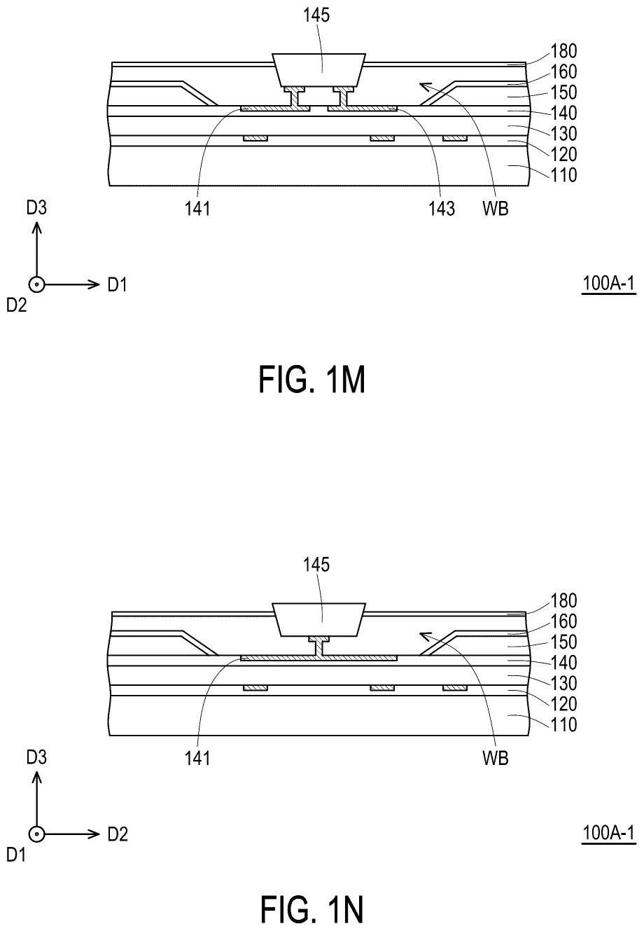

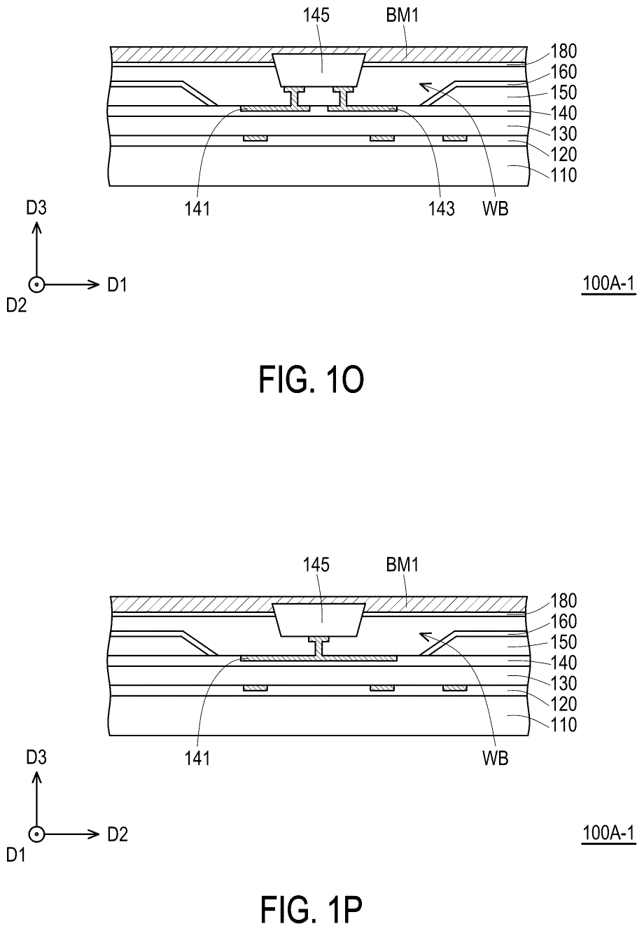

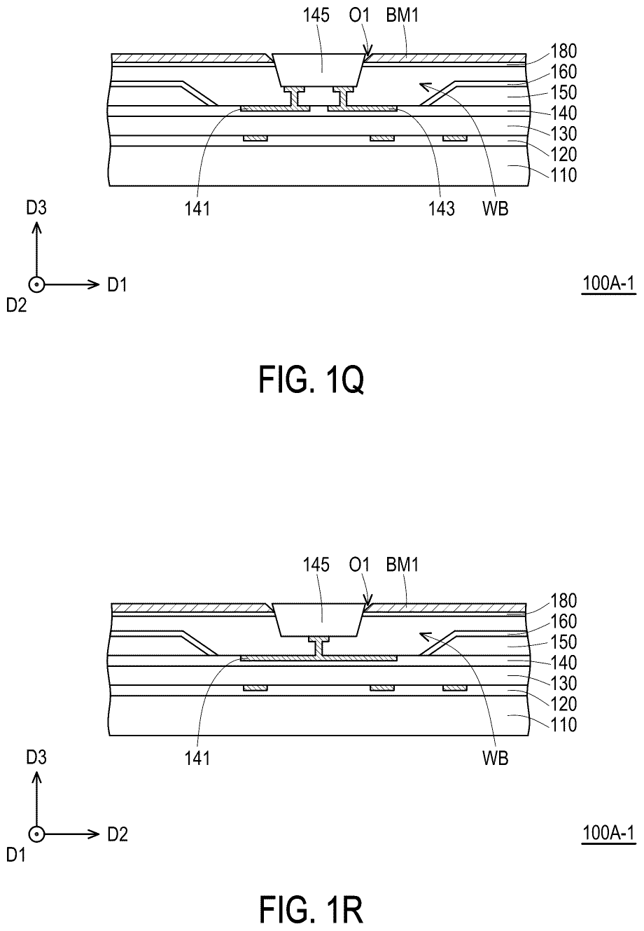

FIG. 1A to FIG. 1R are schematic diagrams of partial process flows of a display device manufacturing method according to the disclosure. Referring to FIG. 1A and FIG. 1B, a display device 100A includes a first substrate 110, an insulation layer 120, an insulation layer 130, and an insulation layer 140 disposed sequentially on the first substrate 110, and an electrode 141 and an electrode 143 are disposed on the insulation layer 140. As shown in FIG. 1A, when viewed along a first direction D1, a first light-emitting unit 145 is electrically connected to the electrode 141 and the electrode 143, and as shown in FIG. 1B, when viewed along a second direction D2, the first light-emitting unit 145 is electrically connected to the electrode 141. On the insulation layer 140, a planarization layer 150 is disposed surrounding the electrode 141 and the electrode 143 in the first direction D1 or surrounding the electrode 141 in the second direction D2, and the planarization layer 150 and the electrode 141 or the electrode 143 do not overlap in a normal direction of the first substrate 110. The insulation layer 160 covering the planarization layer 150 is disposed on the planarization layer 150, and then a barrier layer WB covering the insulation layer 140, the electrode 141, the electrode 143, the insulation layer 160, and the first light-emitting unit 145 is disposed.

Referring to FIG. 1C and FIG. 1D, a height H1 is defined as the height along a third direction D3 between a top surface 145T of the first light-emitting unit 145 and a first surface 140S1 of the insulation layer 140, and a height H2 is defined as the height along the third direction D3 between a top surface WBT of the barrier layer WB and the first surface 140S1 of the insulation layer 140. By utilizing topographical difference, the barrier layer WB is made to conformally cover and flow along the topography, such that in the normal direction (that is, the third direction D3) of the first substrate 110, the height of the barrier layer WB that does not overlap with the first light-emitting unit 145 is lower, and the value of the height H2 is therefore smaller than the value of height H1. In some embodiments, a ratio range of the height H2 to the height H1 is, for example, 70% to 50%.

Referring to FIG. 1E and FIG. 1F, since the remaining thin barrier layer WB portion on the top surface 145T of the first light-emitting unit 145 and the top surface WBT of the barrier layer WB form a height difference, for the remaining thin barrier layer WB portion on the top surface 145T of the first light-emitting unit 145, blanket exposure and development technology is used. By utilizing the characteristic that thin films above micro light-emitting diodes are easier to strip during development, the top surface 145T and partial side surfaces of the first light-emitting unit 145 may be exposed after exposure and development. Referring to FIG. 1E and FIG. 1F, the remaining portion of the barrier layer WB proceeds to cover the first light-emitting unit 145, forming the barrier layer WB that is self-aligned to the position of the first light-emitting unit 145. Thus, the first light-emitting unit 145 is not affected by the misalignment of the micro light-emitting diode.

In this embodiment, the height H1 of the first light-emitting unit 145 is, for example, 10 micrometers, the height between the top surface of the barrier layer WB above the top surface 145T of the first light-emitting unit 145 and the first surface 140S1 of the insulation layer 140 before development is, for example, 15 micrometers, the ratio range of H1 to this height is, for example, 104% to 128%, and the height H2 of the barrier layer WB after development is, for example, 5 micrometers. By utilizing the structure and process of the aforementioned covering type barrier layer WB, the problem of misalignment of the first light-emitting unit 145 encountered during exposure and development processes may be effectively avoided, thereby enabling the first light-emitting unit 145 to maintain stable light emission efficiency, which is approximately 28% more compared to conventional technology. Additionally, due to the reduction of misalignment of the first light-emitting unit 145, the light emission performance and production yield of the display device have significant improvement, thereby enabling the display device to have advantages such as energy saving and reduced production costs.

Referring to FIG. 1G and FIG. 1H, a first light-shielding layer BM1 is disposed on the barrier layer WB and the first light-emitting unit 145. Referring to FIG. 1I and FIG. 1J, by utilizing exposure and development technology, the first light-shielding layer BM1 covering the top surface 145T of the first light-emitting unit 145 is removed, enabling the first light-shielding layer BM1 to form a first opening O1. Thus, the barrier layer WB may completely conform to and cover the first light-emitting unit 145 while the first light-shielding layer BM1 does not cover the light-emitting surface, improving the light emission efficiency of the display device.

FIG. 1K to FIG. 1R show partial process flow diagrams of a display device manufacturing method according to another embodiment of the disclosure. Referring to FIG. 1K and FIG. 1L, in a display device 100A-1 of this embodiment, a covering layer 180 is disposed on the barrier layer WB and the top surface 145T of the first light-emitting unit 145. By utilizing exposure and development technology, the covering layer 180 disposed on the top surface 145T of the first light-emitting unit 145 is removed. Referring to FIG. 10 and FIG. 1P, the first light-shielding layer BM1 is disposed on the covering layer 180 and the first light-emitting unit 145, and by utilizing exposure and development technology, the first light-shielding layer BM1 covering the top surface 145T of the first light-emitting unit 145 is removed, enabling the first light-shielding layer BM1 to form the first opening O1. Thus, the barrier layer WB and the covering layer 180 may completely conform to and cover the first light-emitting unit 145 while the first light-shielding layer BM1 does not cover the light-emitting surface, improving the light emission efficiency of the display device.

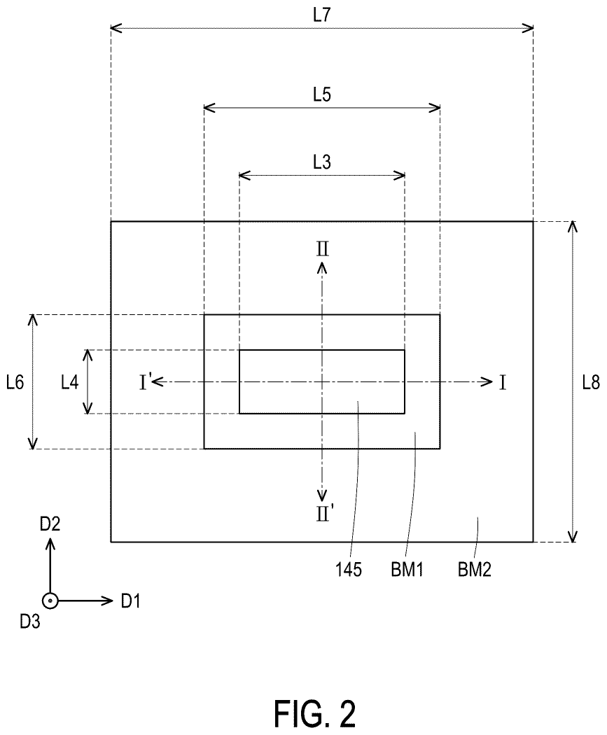

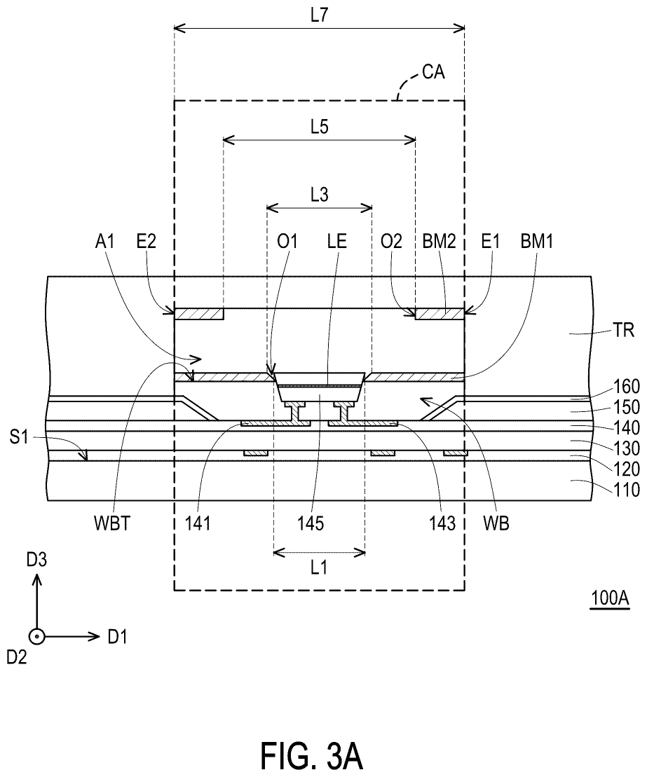

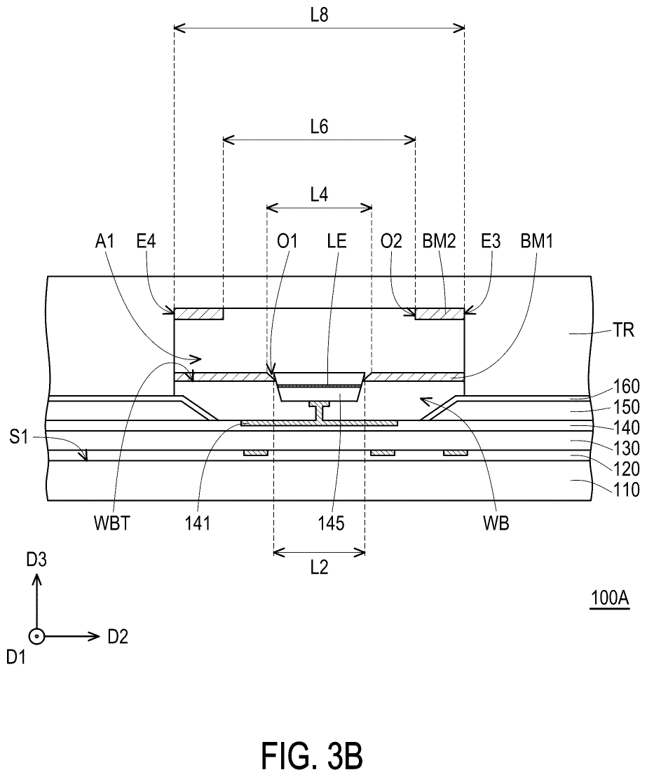

FIG. 2 is a top view diagram of a display device according to an embodiment of the disclosure. FIG. 3A is a cross-sectional diagram of the display device along I-I′ according to FIG. 2. FIG. 3B is a cross-sectional diagram of the display device along II-II′ according to FIG. 2. Referring to FIG. 2, FIG. 3A, and FIG. 3B simultaneously, the display device 100A further includes a second barrier layer BM2 and a first dielectric layer A1. The first dielectric layer A1 is positioned on the first light-emitting unit 145, the first light-emitting unit 145 includes a light-emitting layer LE, and the light-emitting layer LE may include organic light-emitting material layer (OLED) or inorganic light-emitting material, but the disclosure is not limited thereto. In some embodiments, the light-emitting layer LE may include, for example, a hole injection layer, a hole transport layer, a light-emitting material layer, an electron transport layer, and an electron injection layer, but the disclosure is not limited thereto. The first light-emitting unit 145 is disposed on the first substrate 110, the display device includes a groove area CA, the first light-emitting unit 145 is disposed in the groove area CA, the barrier layer WB surrounds the first light-emitting unit 145, and a distance between the top surface WBT of the barrier layer WB and a first surface S1 of the first substrate 110 along the third direction D3 is greater than a distance between the light-emitting layer LE and the first surface S1 of the first substrate 110 along the third direction D3. The first light-shielding layer BM1 includes the first opening O1, is disposed on the first substrate 110, and surrounds the first light-emitting unit 145. The second barrier layer BM2 is disposed on the first light-shielding layer BM1 and has a second opening O2. The first dielectric layer A1 has a first refractive index n1, is disposed between the first light-shielding layer BM1 and the second barrier layer BM2, and is positioned on the first light-emitting unit 145.

In an embodiment of the disclosure, the first substrate 110 may be a circuit board, active component substrate, or other plate-like structure that may be used to provide driving signals and/or power to the first light-emitting unit 145 and may support the first light-emitting unit 145. In some embodiments, when the first substrate 110 is a circuit board, the first substrate 110 may include multiple conductive circuit layers and multiple insulation layers used to separate the multiple conductive circuit layers, but the disclosure is not limited thereto. Specifically, the first substrate 110 includes the electrode 141 and the electrode 143 for electrically connecting the first light-emitting unit 145, and the electrode 141 and the electrode 143 are positioned on the surface of the first substrate 110 facing the first light-emitting unit 145. The first light-emitting unit 145 may be coupled to corresponding pads on the first substrate 110 through conductive bonding material, and electrically connected with corresponding electrodes.

The first light-emitting unit 145 is, for example, a light-emitting diode. The light-emitting diode may include, for example, organic light emitting diode (OLED), mini LED, micro LED, or quantum dot light-emitting diode (quantum dot, QD, which may be, for example, QLED, QDLED), fluorescence, phosphor, or other suitable materials, and the materials thereof may be arranged and combined in any manner, but the disclosure is not limited thereto. In some embodiments, the first light-emitting unit 145 may be a light-emitting chip, and the first light-emitting unit 145 may be coupled to the first substrate 110 in the form of chip on board (COB), that is, the first light-emitting unit 145 may be electrically connected to circuits on the first substrate 110.

Referring to FIG. 3A and FIG. 3B, the first light-emitting unit 145 has a first length L1 along the first direction D1 and has a second length L2 along the second direction D2, the first opening O1 has a third length L3 along the first direction D1, the first opening O1 has a fourth length L4 along the second direction D2, the second opening O2 has a fifth length L5 along the first direction D1, the second opening O2 has a sixth length L6 along the second direction D2, a first side E1 and a second side E2 of a second light-shielding layer BM2 have a seventh length L7 along the first direction D1, a third side E3 and a fourth side E4 of the second light-shielding layer BM2 have an eighth length L8 along the second direction D2, the fifth length L5 is greater than the third length L3, the sixth length L6 is greater than the fourth length L4, the fifth length L5 is greater than the first length L1, the sixth length L6 is greater than the second length L2, the difference between the third length L3 and the first length L1 is less than or equal to 3 micrometers and greater than or equal to zero, and the difference between the fourth length L4 and the second length L2 is less than or equal to 3 micrometers and greater than or equal to zero.

The display device 100A further includes a second dielectric layer TR disposed to surround the first dielectric layer A1. In some embodiments, the second dielectric layer TR may cover the second light-shielding layer BM2 and the first dielectric layer A1, but the disclosure is not limited thereto. The second dielectric layer TR is solid and has a second refractive index n2. The second refractive index n2 is greater than the first refractive index n1, and the first refractive index n1 is greater than 1. The Second refractive index n2 is, for example, 1.5±0.1. The first dielectric layer A1 includes low refractive index medium, solid, gas, vacuum, or organic compound. The first refractive index n1 is less than 1.4, and preferably may be selected such that the first refractive index n1 is less than 1.2. The first dielectric layer A1 is low-density gas. The first dielectric layer A1 is, for example, air. The first dielectric layer A1 is helium, neon, argon, krypton, xenon, or radon.

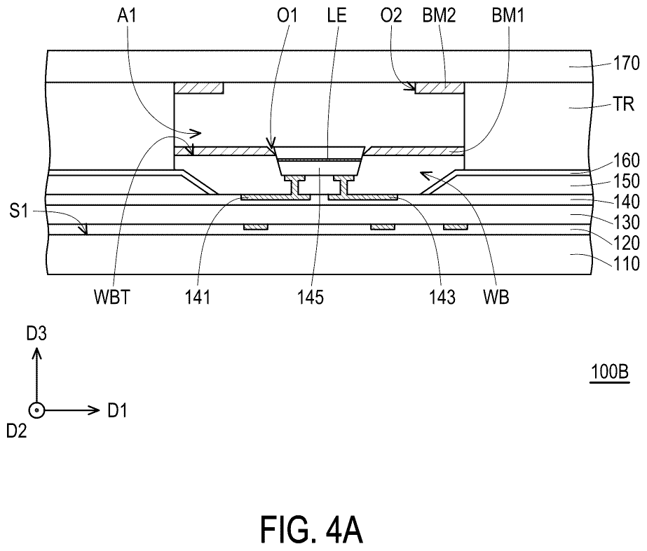

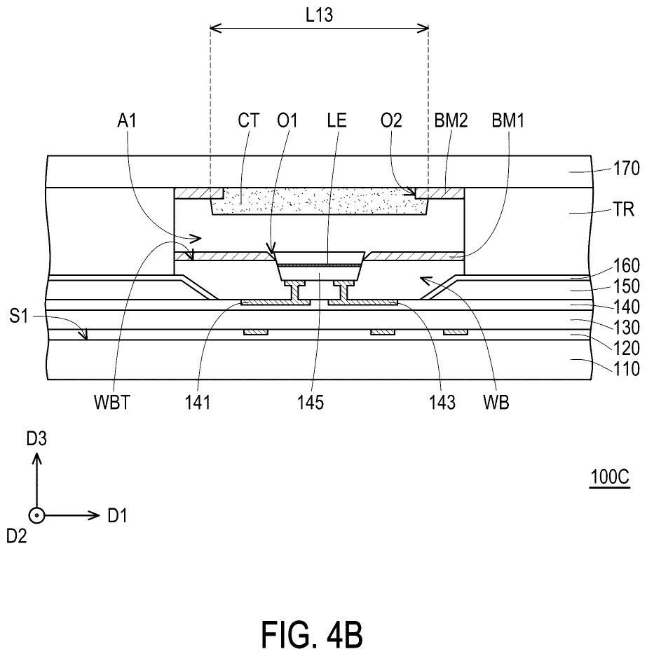

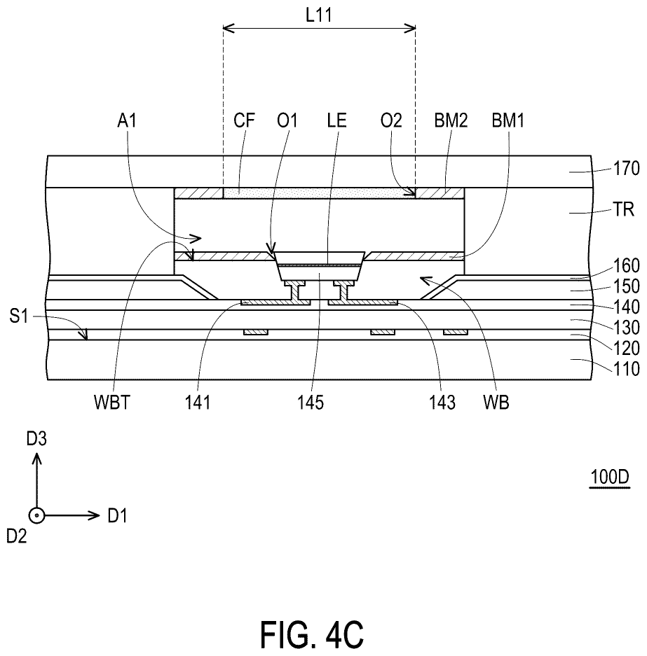

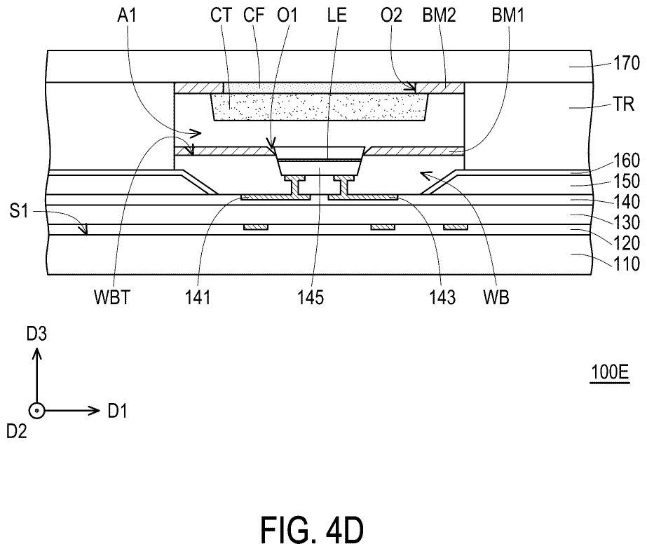

FIG. 4A is a cross-section schematic diagram of a display device according to another embodiment of the disclosure. A display device 100B is similar to the display device 100A, with the main difference being that the display device 100B further includes a second substrate 170. The second substrate 170 is disposed on the first substrate 110, the second dielectric layer TR is located between the second substrate 170 and the insulation layer 160, the second dielectric layer TR is disposed to surround the first dielectric layer A1, the second light-shielding layer BM2 is disposed on the second substrate 170, the second light-shielding layer BM2 is located between first light-shielding layer BM1 and the second substrate 170, and the second substrate 170 is disposed on the first dielectric layer A1. The second substrate 170 has a third refractive index n3, and the absolute value of the difference between the third refractive index and the second refractive index n2 is less than or equal to 0.2.

FIG. 4B is a cross-section schematic diagram of a display device according to another embodiment of the disclosure. A display device 100C is similar to the display device 100B, with the main difference being that the display device 100C further includes a color conversion layer CT. The color conversion layer CT has the first refractive index n1, the color conversion layer CT is disposed in the second opening O2, and the color conversion layer CT overlaps the first light-emitting unit 145 in the normal direction of the first substrate 110. The color conversion layer CT has a thirteenth length L13 along the first direction D1, and the thirteenth length L13 is less than 200% of the fifth length L5.

FIG. 4C is a cross-section schematic diagram of a display device according to another embodiment of the disclosure. A display device 100D is similar to the display device 100B, with the main difference being that the display device 100D further includes an optical filter layer CF. The optical filter layer CF is disposed in the second opening O2, and the optical filter layer CF overlaps the first light-emitting unit 145 in the normal direction of the first substrate 110. The optical filter layer CF has an eleventh length L11 along the first direction D1, and the eleventh length L11 is greater than the fifth length L5.

FIG. 4D is a cross-section schematic diagram of a display device according to another embodiment of the disclosure. A display device 100E is similar to the display device 100B, with the main difference being that the display device 100E further includes the optical filter layer CF and the color conversion layer CT. The optical filter layer CF and the color conversion layer CT are disposed in the second opening O2, the optical filter layer CF is disposed on the color conversion layer CT, and the optical filter layer CF and the color conversion layer CT overlap the first light-emitting unit 145 in the normal direction of the first substrate 110. In this embodiment, the color conversion layer CT has the second refractive index n2.

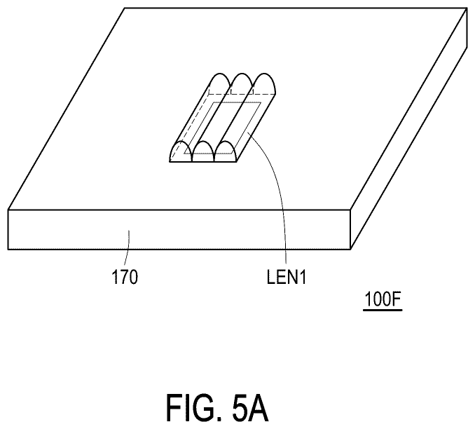

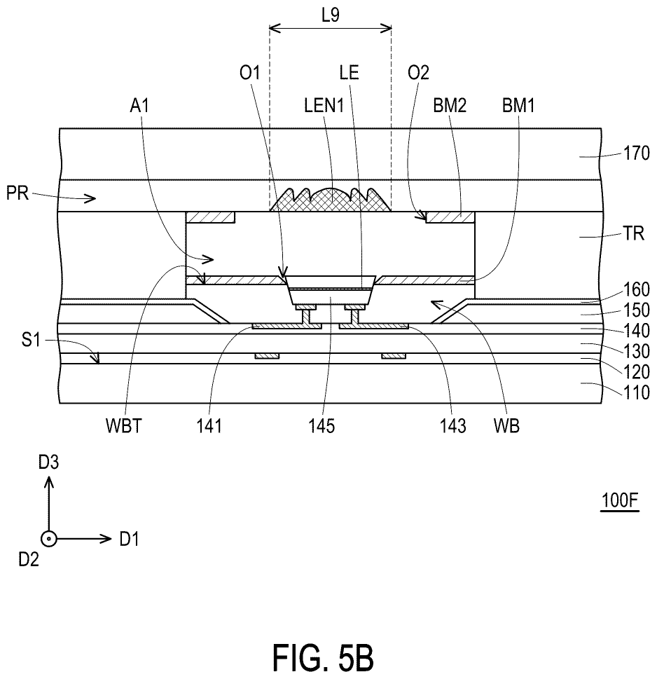

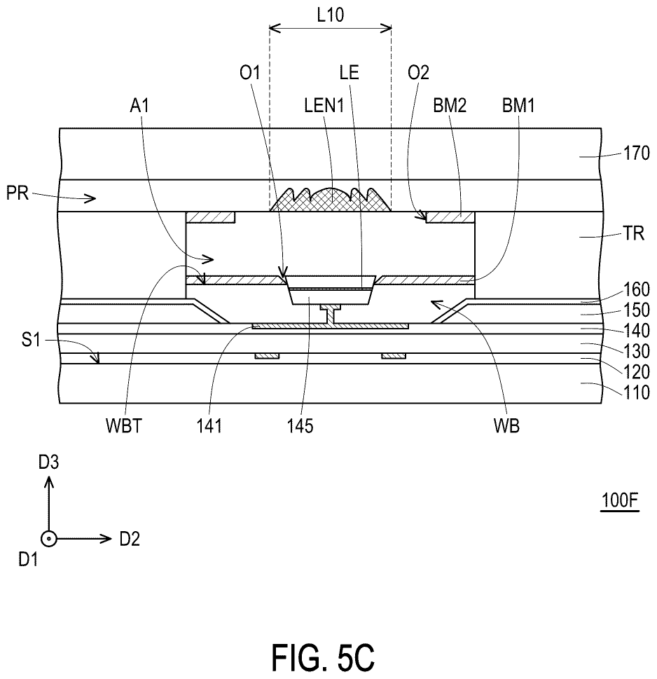

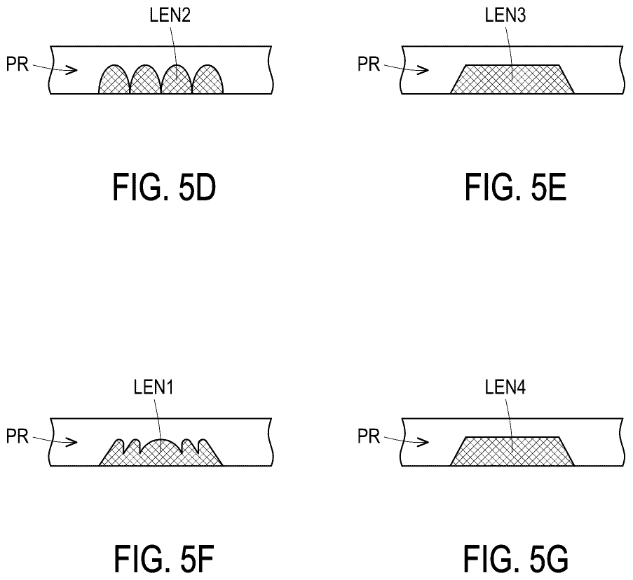

FIG. 5A is a top view schematic diagram of a display device according to another embodiment of the disclosure. FIG. 5B and FIG. 5C are cross-section schematic diagrams according to the display device in FIG. 5A. Please refer to FIG. 5A to FIG. 5C simultaneously.

A display device 100F is similar to the display device 100B, with the main difference being that the display device 100F further includes a photoresist layer PR and a lens layer LEN1. The photoresist layer PR is disposed between the second substrate 170 and the first substrate 110, the photoresist layer PR is positioned on the second light-shielding layer BM2, the second dielectric layer TR and the first dielectric layer A1, the lens layer LEN1 is disposed in the second opening O2, the lens layer LEN1 is positioned on the first dielectric layer A1, the photoresist layer PR covers the lens layer LEN1, and the lens layer LEN1 overlaps the first light-emitting unit 145 in the normal direction of the first substrate 110. The lens layer LEN1 has a ninth length L9 along the first direction D1 and has a tenth length L10 along the second direction. In some embodiments, when the display device 100F is a non-transparent display device, the fifth length L5 is less than the ninth length L9, the ninth length L9 may be less than 200% of the fifth length L5, the sixth length L6 may be less than the tenth length L10 and the tenth length L10 may be less than 200% of the sixth length L6. When the display device 100F is a transparent display device, the ninth length L9 may be less than the seventh length L7 and the tenth length L10 may be less than the eighth length L8.

FIG. 5D to FIG. 5G are enlarged schematic diagrams of the lens layer according to FIG. 5B or FIG. 5C. In FIG. 5D, a lens layer LEN2 of the display device 100F may be a lens array layer, the lens array layer includes multiple lens elements arranged along the first direction D1, the photoresist layer PR covers the lens layer LEN2 and the lens layer LEN2 overlaps the first light-emitting unit 145 in the normal direction of the first substrate 110.

In FIG. 5E, a lens layer LEN3 of the display device 100F may be a single lens element, the photoresist layer PR covers the lens layer LEN1 and the lens layer LEN1 overlaps the first light-emitting unit 145 in the normal direction of the first substrate 110.

In FIG. 5E, the lens layer LEN1 of the display device 100F may be a Fresnel lens element or similar structure. Based on the process, the Fresnel lens element has characteristics such as collimation, light concentration, and maximum front viewing angle luminance gain. The photoresist layer PR covers the lens layer LEN1 and the lens layer LEN1 overlaps the first light-emitting unit 145 in the normal direction of the first substrate 110.

In FIG. 5E, a lens layer LEN4 of the display device 100F may be a flat-top pyramid lens element, the photoresist layer PR covers the lens layer LEN4, and the lens layer LEN4 overlaps the first light-emitting unit 145 in the normal direction of the first substrate 110.

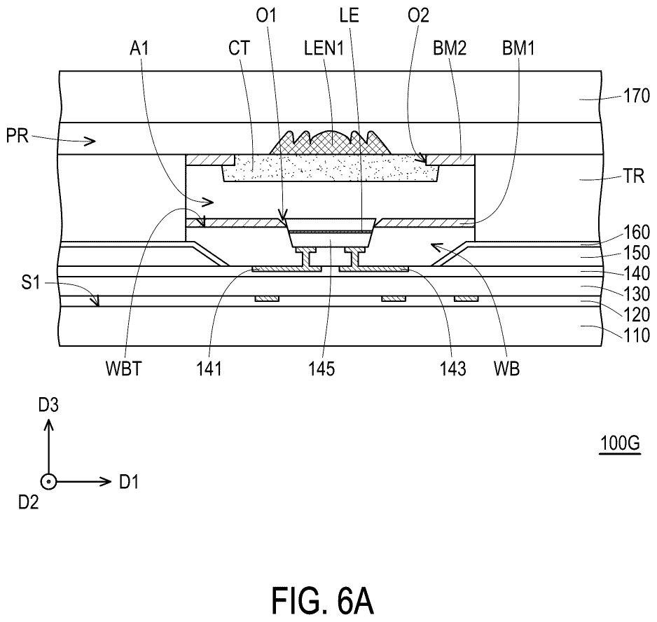

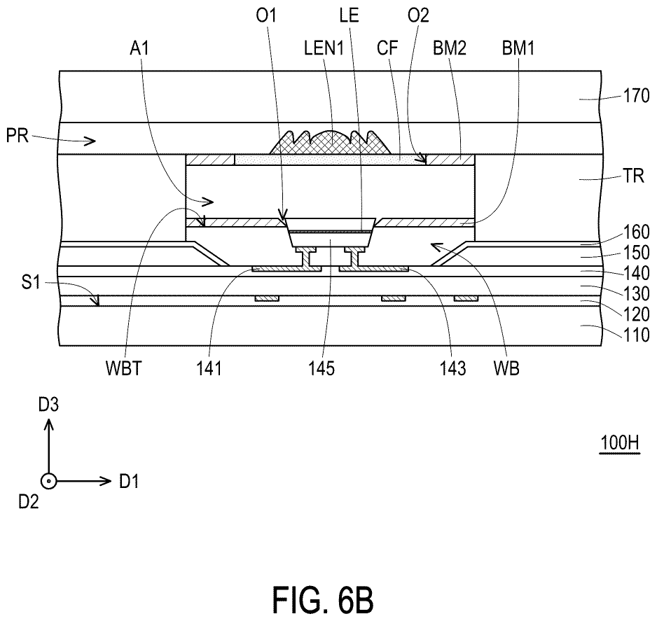

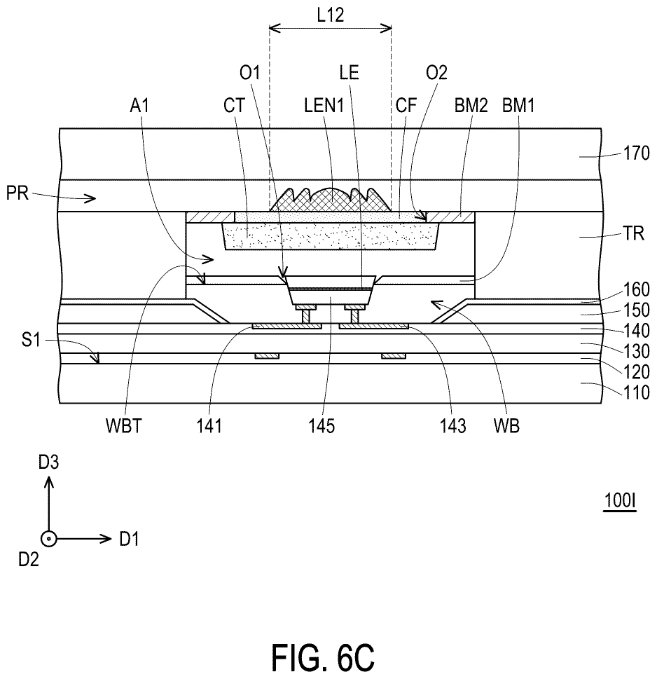

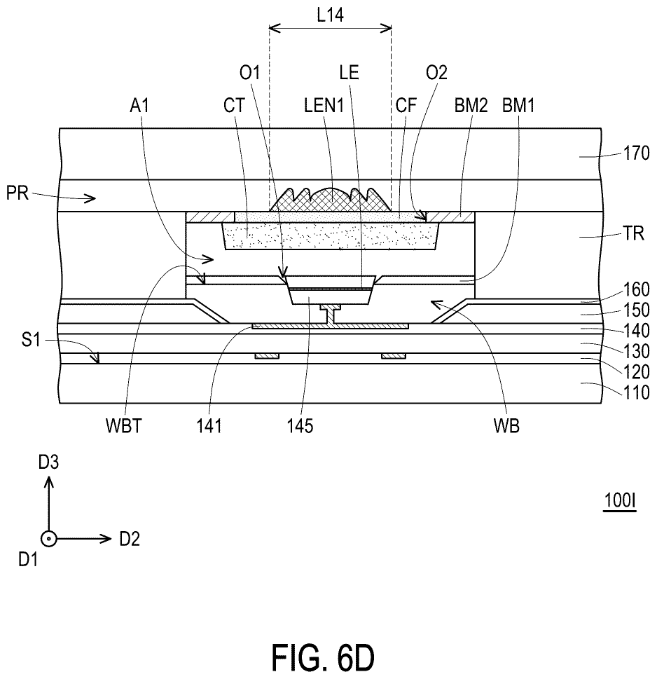

FIG. 6A is a cross-section schematic diagram of a display device according to another embodiment of the disclosure. A display device 100G is similar to the display device 100C, with the main difference being that the display device 100G further includes the photoresist layer PR and the lens layer LEN1, the photoresist layer PR is disposed between the second substrate 170 and the first substrate 110, the photoresist layer PR is positioned on the second light-shielding layer BM2 and the second dielectric layer TR as well as the color conversion layer CT, and the lens layer LEN1 is disposed in the second opening O2 and positioned on the color conversion layer CT. In this embodiment, the color conversion layer CT may have the third refractive index n3.

FIG. 6B is a cross-section schematic diagram of a display device according to another embodiment of the disclosure. A display device 100H is similar to the display device 100D, with the main difference being that the display device 100H further includes the photoresist layer PR and the lens layer LEN1, the photoresist layer PR is disposed between the second substrate 170 and the first substrate 110, the photoresist layer PR is positioned on the second light-shielding layer BM2 and the second dielectric layer TR as well as the optical filter layer CF, and the lens layer LEN1 is disposed in the second opening O2 and positioned on the optical filter layer CF.

FIG. 6C and FIG. 6D are cross-section schematic diagrams of a display device according to another embodiment of the disclosure. A display device 100I is similar to the display device 100E, with the main difference being that the display device 100I further includes the photoresist layer PR and the lens layer LEN1, the photoresist layer PR is disposed between the second substrate 170 and the first substrate 110, the photoresist layer PR is positioned on the second light-shielding layer BM2 and the second dielectric layer TR as well as the optical filter layer CF and the color conversion layer CT, and the lens layer LEN1 is disposed in the second opening O2 and positioned on the optical filter layer CF and the color conversion layer CT.

The lens layer LEN1 has a twelfth length L12 along the first direction D1, the lens layer LEN1 has a fourteenth length L14 along the second direction D2, in some embodiments, when the display device 100I is a non-transparent display device, the sixth length L6 is smaller than the twelfth length L12, and the fourteenth length L14 is smaller than 200% of the sixth length L6. When the display device 100I is a transparent display device, the twelfth length L12 and the fourteenth length L14 are smaller than the eighth length L8. In an embodiment of the disclosure, the twelfth length L12 and the fourteenth length L14 of the lens layer LEN1 are also applicable to the lens layers LEN2, LEN3, and LEN4, and the relationship between the lens layer LEN1 and other lengths (for example, the sixth length L6 or the eighth length L8) is also applicable to the LEN2, LEN3, and LEN4, but the disclosure is not limited thereto.

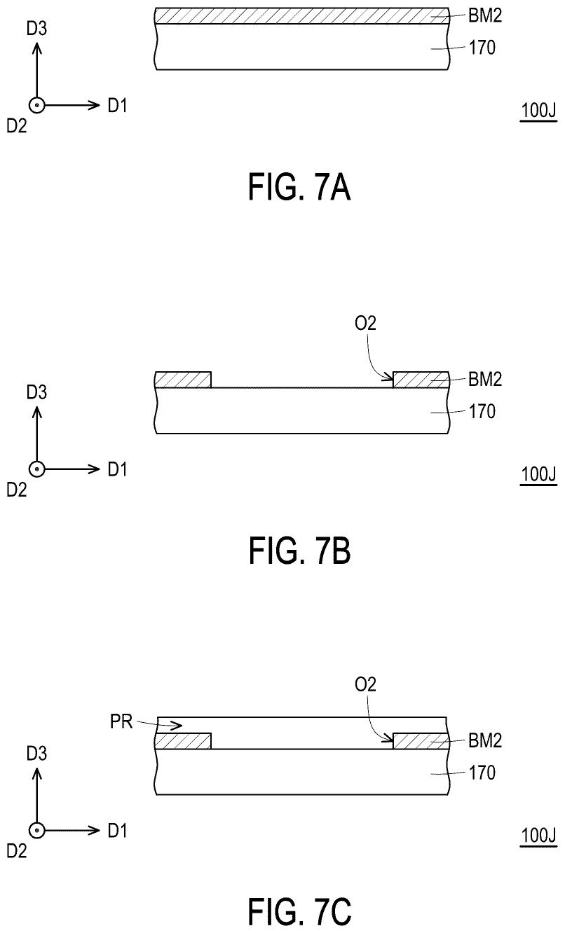

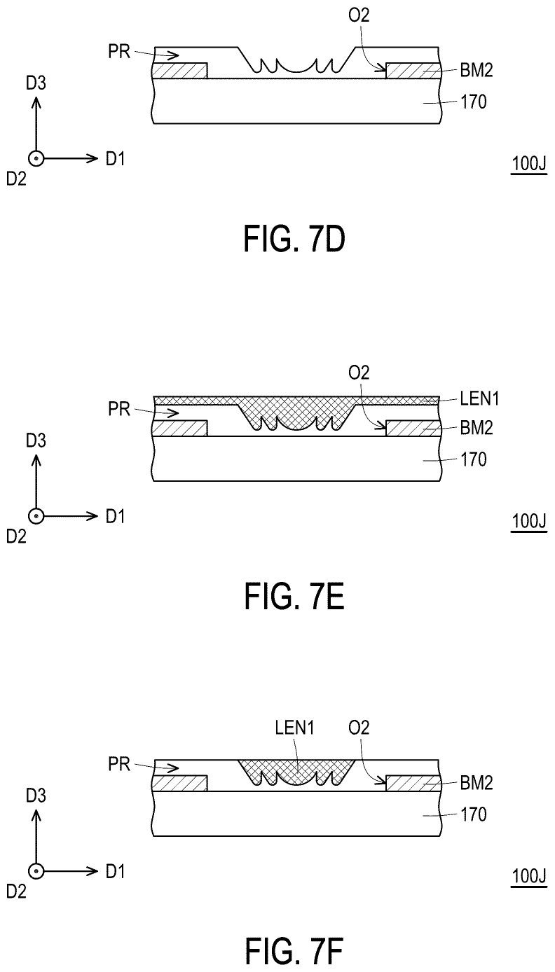

FIG. 7A to FIG. 7F show schematic diagrams of partial process flows of a display device manufacturing method according to another embodiment of the disclosure. This embodiment is similar to the structure of FIG. 5B, and the same parts as FIG. 5B are omitted here, only the different parts are described. Referring to FIG. 7A, a display device 100J is similar to the display device 100F, the main difference is that the display device 100J disposes the second light-shielding layer BM2 on the surface of the second substrate 170 away from the first substrate 110. Referring to FIG. 7B, by using blanket exposure and development technology, the opening O2 is formed in the second light-shielding layer BM2. Referring to FIG. 7C, the photoresist layer PR is disposed in the second opening O2 and on the second light-shielding layer BM2, and the photoresist layer PR covers the second substrate 170, by using blanket exposure and development technology, on the photoresist layer PR, at positions overlapping the first light-emitting unit 145 in the normal direction of the first substrate 110, morphology such as the lens layer LEN1, LEN2, LEN3, or LEN4 is formed. Referring to FIG. 7F, portions of the lens layer at positions not overlapping the first light-emitting unit 145 in the normal direction of the first substrate 110 are removed by using exposure and development technology.

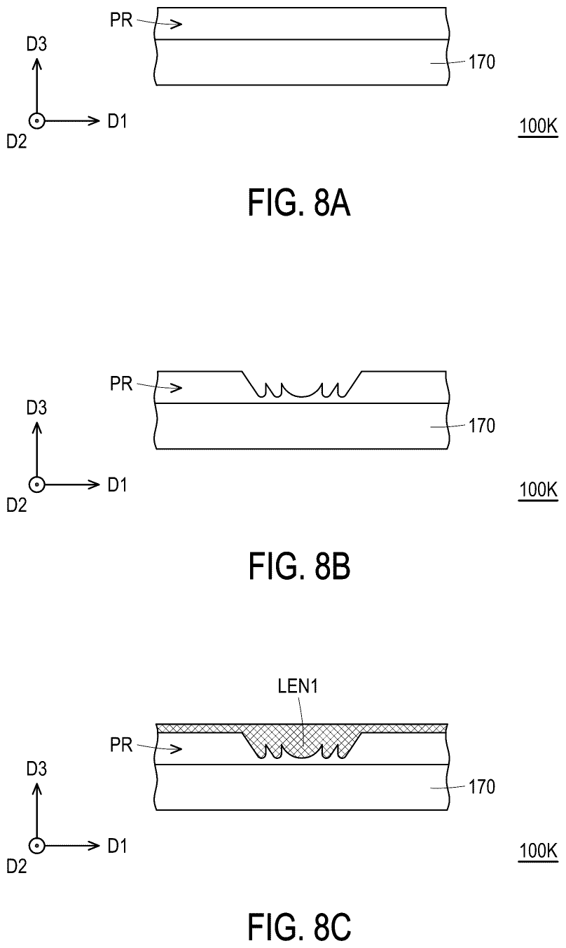

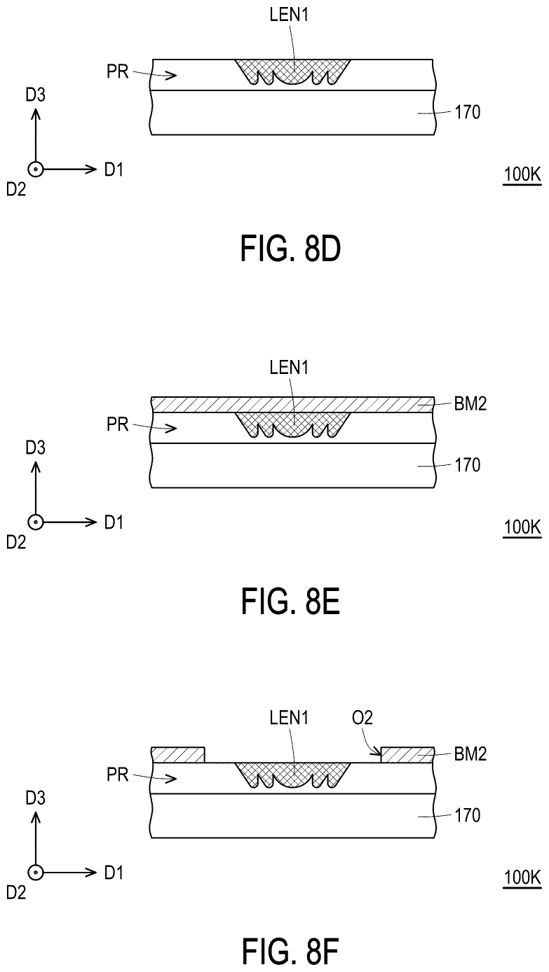

FIG. 8A to FIG. 8F show schematic diagrams of partial process flows of a display device manufacturing method according to another embodiment of the disclosure. A display device 100K is similar to the display device 100J, with the main difference being that the second light-shielding layer BM2 in the display device 100K is disposed on the photoresist layer PR, that is, the lens layer is located between the second light-shielding layer BM2 and the second substrate 170.

In summary, in the display device of embodiments of the disclosure, the distance between the top surface of the barrier layer and the first surface of the first substrate along the third direction is greater than the distance between the light-emitting layer and the first surface of the first substrate, the first light-shielding layer includes a first opening, the second light-shielding layer is disposed on the first light-shielding layer and has a second opening, the first dielectric layer has a first refractive index and is disposed between the first light-shielding layer and the second light-shielding layer and located on the first light-emitting unit, the first light-emitting unit has a first length along the first direction and has a second length along the second direction, the first opening has a third length along the first direction, the first opening has a fourth length along the second direction, the second opening has a fifth length along the first direction, the second opening has a sixth length along the second direction, the fifth length is greater than the third length, the sixth length is greater than the fourth length, the fifth length is greater than the first length, the sixth length is greater than the second length, and the difference between the third length and the first length is less than or equal to 3 micrometers and greater than or equal to zero and the difference between the fourth length and the second length is less than or equal to 3 micrometers and greater than or equal to zero. In this way, through the foregoing design, the display device may have low viewing angle color shift and low reflection performance while being able to more efficiently enhance the packaging architecture.

What is claimed is:

1. A display device, comprising:
a first substrate;
a first light-emitting unit comprising a light-emitting layer and disposed on the first substrate, wherein the display device comprises a groove area, and the first light-emitting unit is disposed in the groove area;
a barrier layer surrounding the first light-emitting unit, wherein the barrier layer has a top surface, and a distance between the top surface and a first surface of the first substrate along a third direction is greater than a distance between the light-emitting layer and the first surface of the first substrate;
a first light-shielding layer comprising a first opening, disposed on the first substrate, and surrounding the first light-emitting unit;
a second light-shielding layer disposed on the first light-shielding layer, and having a second opening;
a first dielectric layer having a first refractive index, disposed between the first light-shielding layer and the second light-shielding layer, and positioned on the first light-emitting unit,
wherein the first light-emitting unit has a first length along a first direction and has a second length along a second direction, the first opening has a third length along the first direction, the first opening has a fourth length along the second direction, the second opening has a fifth length along the first direction, the second opening has a sixth length along the second direction, the fifth length is greater than the third length, the sixth length is greater than the fourth length, the fifth length is greater than the first length, the sixth length is greater than the second length, a difference between the third length and the first length is less than or equal to 3 micrometers and greater than or equal to zero, and a difference between the fourth length and the second length is less than or equal to 3 micrometers and greater than or equal to zero.

2. The display device according to claim 1, further comprising a second dielectric layer disposed to surround the first dielectric layer, wherein the second dielectric layer has a second refractive index, the second refractive index is greater than the first refractive index, and the first refractive index is greater than 1.

3. The display device according to claim 1, wherein the first dielectric layer comprises gas and organic compound.

4. The display device according to claim 1, wherein the first refractive index is less than 1.4.

5. The display device according to claim 1, wherein the first refractive index is less than 1.2.

6. The display device according to claim 5, wherein the first dielectric layer is low-density gas.

7. The display device according to claim 5, wherein the first dielectric layer is air.

8. The display device according to claim 5, wherein the first dielectric layer is helium, neon, argon, krypton, xenon, or radon.

9. The display device according to claim 1, further comprising a second substrate, wherein the second light-shielding layer is disposed on the second substrate, and the second light-shielding layer is located between the first light-shielding layer and the second substrate.

10. The display device according to claim 1, further comprising a second dielectric layer and a second substrate, wherein the second dielectric layer is disposed to surround the first dielectric layer, the second substrate is disposed on the first substrate, the second dielectric layer has a second refractive index, the second substrate has a third refractive index, and an absolute value of a difference between the third refractive index and the second refractive index is less than or equal to 0.2.

11. The display device according to claim 1, further comprising a color conversion layer, wherein the color conversion layer is disposed in the second opening, and the color conversion layer overlaps the first light-emitting unit in a normal direction of the first substrate.

12. The display device according to claim 11, wherein the color conversion layer has the first refractive index.

13. The display device according to claim 1, further comprising an optical filter layer, wherein the optical filter layer is disposed in the second opening, and the optical filter layer overlaps the first light-emitting unit in a normal direction of the first substrate.

14. The display device according to claim 1, further comprising an optical filter layer and a color conversion layer, wherein the optical filter layer and the color conversion layer are disposed in the second opening, the optical filter layer is disposed on the color conversion layer, and the optical filter layer and the color conversion layer overlap the first light-emitting unit in a normal direction of the first substrate.

15. The display device according to claim 14, wherein the color conversion layer has a second refractive index.

16. The display device according to claim 1, further comprising a lens layer and a photoresist layer, wherein the lens layer is disposed at the second opening, the photoresist layer covers the lens layer, and the lens layer overlaps the first light-emitting unit in a normal direction of the first substrate.

17. The display device according to claim 16, wherein a refractive index of the lens layer is greater than a refractive index of the photoresist layer.

18. The display device according to claim 16, wherein the lens layer is a Fresnel lens element.

19. The display device according to claim 16, wherein the lens layer is a lenticular lens element.

20. The display device according to claim 16, wherein the lens layer is a pyramid lens element.

21. The display device according to claim 20, wherein the pyramid lens element has a flat top.

22. The display device according to claim 1, further comprising a lens layer and a photoresist layer, wherein the lens layer is disposed at the second opening, the lens layer is a lens array layer, the lens array layer comprises a plurality of lens elements arranged along the first direction, the photoresist layer covers the lens layer, and the lens layer overlaps the first light-emitting unit in a normal direction of the first substrate.

23. The display device according to claim 1, further comprising an optical filter layer, a color conversion layer, and a lens layer, wherein the optical filter layer and the color conversion layer and the lens layer are disposed in the second opening, the optical filter layer is disposed on the color conversion layer, the lens layer is disposed on the optical filter layer, and the optical filter layer and the color conversion layer and the lens layer overlap the first light-emitting unit in a normal direction of the first substrate.

24. The display device according to claim 23, wherein the color conversion layer has a third refractive index.

25. A display device, comprising:
a first substrate;
a first light-emitting unit comprising a light-emitting layer and disposed on the first substrate, wherein the display device comprises a groove area, and the first light-emitting unit is disposed in the groove area;
a barrier layer surrounding the first light-emitting unit, wherein the barrier layer has a top surface, and a distance between the top surface and a first surface of the first substrate along a third direction is greater than a distance between the light-emitting layer and the first surface of the first substrate;
a first light-shielding layer comprising a first opening, disposed on the first substrate, and surrounding the first light-emitting unit;
a second light-shielding layer disposed on the first light-shielding layer, and having a second opening;
a first dielectric layer having a first refractive index, disposed between the first light-shielding layer and the second light-shielding layer, and positioned on the first light-emitting unit; and
a second dielectric layer disposed to surround the first dielectric layer, wherein the second dielectric layer has a second refractive index, the second refractive index is greater than the first refractive index, and the first refractive index is greater than 1,
wherein the first light-emitting unit has a first length along a first direction and has a second length along a second direction, the first opening has a third length along the first direction, the first opening has a fourth length along the second direction, the second opening has a fifth length along the first direction, the second opening has a sixth length along the second direction, the fifth length is greater than the third length, the sixth length is greater than the fourth length, the fifth length is greater than the first length, the sixth length is greater than the second length, a difference between the third length and the first length is less than or equal to 3 micrometers and greater than or equal to zero, and a difference between the fourth length and the second length is less than or equal to 3 micrometers and greater than or equal to zero.
